(19) United States
(12) Patent Application Publication
(10) Pub. No.: US 2013/0107566 A1
(43) Pub. Date: May 2, 2013

(54) EDGE ILLUMINABLE WAYFINDER

(71) Applicant: David E. Patterson, Corrales, NM (US)

(72) Inventor: David E. Patterson, Corrales, NM (US)

(73) Assignee: Insight Lighting, Inc., a New Mexico corporation, Rio Rancho, NM (US)

(21) Appl. No.: 13/283,726

(22) Filed: Oct. 28, 2011

(51) Int. Cl. G09F 13/18; H05K 13/00; G09F 13/04

(52) U.S. Cl. 362/602; 29/825

(57) ABSTRACT

The specification and drawing figures describe and show an edge illuminable wayfinder that includes a an illuminable graphic sandwich operatively connectable to a sealed light-emitting diode platform that are enclosed in a housing.

### FIELD OF TECHNOLOGY

The apparatus, systems and methods disclosed, illustrated and claimed in this document pertaining generally to signs. More particularly, the new and useful edge illuminable wayfinder disclosed and claimed in this document pertains to signage that is uniformly brightly illuminable, allows in situ changes to the graphics of the signage, and includes means for illuminating the signage that is removably replaceable following installation of the wayfinder in an operational environment. The edge illuminable wayfinder is particularly, but not exclusively, useful for directing visitors through public environments including but not limited to airports, malls, sports facilities, ground transportation depots, and other locations in which people must move from one place to another.

### BACKGROUND

Until now, conventional wayfinder products have been back-lit through a single diffusion panel. In such conventional wayfinder products the source of light has been positioned behind the panel on which graphics have been substantially permanently mounted with substantially permanent wayfinding instructions. Conventional wayfinder products are not uniformly illuminable with uniformly bright light.

Limitations associated with such conventional wayfinder products include high operational energy costs attributable to use of light sources that are energy inefficient and excessively costly. It has been estimated that over 90% of energy costs associated with the use of fluorescent or incandescent lighting sources are wasted as heat.

Conventional wayfinder products also fail to include means for field accessibility to removable and replaceable components, a limitation that adds to maintenance costs and, in some instances, replacement of an entire wayfinder product.

A need therefore exists in the industry for new and useful apparatus, systems and methods for uniformly and brightly displaying more than one illuminable graphic capable for displaying identical or different messages and directions in a single wayfinder housing. A need also exists for displaying uniformly illuminable graphics in both dry and wet environments without degradation of the graphic presentation. In addition, a need exists for a wayfinder that is designed for field accessibility to components of the wayfinder in situ in an operational environment to accommodate repairs, component changes, installation of new components, and similar reasons.

### SUMMARY

The apparatus, systems, and methods disclosed, illustrated, and claimed in this document solve the limitations and problems noted above by displaying uniformly and brightly illuminable removable and replaceable selectively dissimilar graphics in dry and wet environments. The solutions are achieved by operatively connecting a sealable light-emitting diode platform to an edge-illuminable graphic sandwich mounted in a housing in such a way that the graphic sandwich, sealable light-emitting diode platform, and other components of the sealed illuminable wayfinder are field-accessible.

More specifically, in one embodiment, a plurality of diodes is positioned on the sealed light-emitting diode platform in such a way that each of at least two lighting panels included in the edge-illuminable graphic sandwich are uniformly and brightly illuminable. If an edge illuminable wayfinder having a single graphic display is needed, a plurality of diodes is positioned on the sealed light-emitting diode platform in such a way that a single lighting panel is uniformly and brightly illuminable. A substantially opaque sheet disposed between opposing inner surfaces of a plurality of engraved lighting panels prevents light from bleeding between the two lighting panels, producing a uniform and bright illumination of wayfinder graphics that are removably positioned on the lighting panels. The combination of components enables the wayfinder to be illuminable by directing the light through a single edge of the illuminable graphic sandwich. Because components of the wayfinder are field accessible, selectively dissimilar graphics may be mounted on opposing outer surfaces of the two lighting panels to provide different information as needed; in other words, a double-faced edge illuminable graphic sandwich with a different graphic on each face is achieved. As indicated, however, the wayfinder also made be placed in an operative environment as a single-faced wayfinder. Accordingly, an apparatus is provided that includes an illuminable graphic sandwich that is operatively connectable to a sealed light-emitting diode platform.

In another embodiment an edge illuminable wayfinder includes an illuminable graphic sandwich that in turn includes one or more layers of materials forming a plurality of engraved lighting panels. A substantially opaque sheet is disposed between opposing inner surfaces of the a plurality of lighting panels. One or more replaceable graphics is mountable on or adjacent to opposing exterior surfaces of the plurality of engraved lighting panels. In addition, a light-emitting diode platform operatively connectable to the illuminable graphic sandwich is provided for displaying the one or more graphics. The light-emitting diode platform is sealed in such a way as to enable operation of the edge illuminable wayfinder in either a wet or dry environment. A housing is provided for removably enclosing the illuminable graphic sandwich and the light-emitting diode platform.

In another embodiment, an illuminating system is provided that includes means for displaying uniformly illuminable graphics. The system also includes means for illuminating the means for displaying uniformly illuminable removable graphics. Also included are means for energizing the means for illuminating the means for displaying uniformly illuminable removable graphics that is operatively connectable to the means for displaying and to the means for illuminating.

In yet another embodiment, a method of uniformly displaying graphics is provided that includes providing an illuminable graphic sandwich, forming a sealable light-emitting diode platform, connecting the illuminable graphic sandwich and the light-emitting diode platform, energizing the sealable light-emitting diode platform, and removably enclosing the illuminable graphic sandwich and the sealable light-emitting diode platform in a housing.

The foregoing has outlined broadly the more important features of the invention to better understand the detailed description that follows, and to better understand the contributions to the art. The edge illuminable wayfinder is not limited in application to the details of construction, and to the arrangements of the components, provided in the following description or drawing figures, but is capable of other embodiments, and of being practiced and carried out in various ways.

The phraseology and terminology employed in this disclosure are for purpose of description, and therefore should not be regarded as limiting. As those skilled in the art will appreciate, the conception on which this disclosure is based readily may be used as a basis for designing other structures, methods, and systems. The claims, therefore, include equivalent constructions. Further, the abstract associated with this disclosure is intended neither to define the edge illuminable wayfinder, which is measured by the claims, nor intended to limit the scope of the claims.

It will become apparent to one skilled in the art that the claimed subject matter as a whole, including the structure of the apparatus, and the cooperation of the elements of the apparatus, combine to result in a number of unexpected advantages and utilities.

The structure and co-operation of structure of the edge illuminable wayfinder will become apparent to those skilled in the art when read in conjunction with the following description, drawing figures, and appended claims.

The novel features of the edge illuminable wayfinder are best understood from the accompanying drawing, considered in connection with the accompanying description of the drawing, in which similar reference characters refer to similar parts, and in which:

### BRIEF DESCRIPTION OF THE DRAWING

FIG. 1 of the drawing is a perspective view of one embodiment of the edge illuminable wayfinder in an operational environment;

FIG. 2 is a front view of an edge illuminable wayfinder with mounting devices and a partially cut-away illustration of an engraved surface on a lighting panel;

FIG. 3A is an exploded front view of an edge illuminable wayfinder of FIG. 2;

FIG. 3B illustrates details of one embodiment of an access plate as shown in FIG. 3A;

FIG. 4 is a perspective view of one embodiment of the light-emitting diode platform;

FIG. 5A is a perspective view of components of the edge-illuminable graphic sandwich; and

FIG. 5B is an end view of the edge-illuminable graphic sandwich of FIG. 5A.

To the extent that the numerical designations in the drawing figures include lower case letters such as “a,b” such designations include multiple references, and the letter “n” in lower case such as “a-n” is intended to express a number of repetitions of the element designated by that numerical reference and subscripts.

### DETAILED DESCRIPTION

### Definitions

As used in this document the term “exemplary” means serving as an example, instance, or illustration; any aspect described in this document as “exemplary” is not intended to mean preferred or advantageous over other aspects or embodiments of the edge illuminable wayfinder.

The term “engraved” means that at least one surface of a lighting panel has been engraved or etched with a series of spaced-apart substantially parallel lines of varying depth, width and spacing that contribute to increasing the uniformity of distribution of light across a lighting panel and to increase the brightness of a lighting panel.

The term “field-accessible” means a condition and/or action involving a component of an edge illuminated wayfinder that may be performed after installation of the wayfinder in an operational environment. Thus, for example, the one or more components of the edge illuminable wayfinder may be changed, removed, replaced or otherwise accessed in situ after installation of the edge illuminable wayfinder in an operational environment.

The term “graphic” and/or “graphics” mean a visual display of words, symbols, pictures and/or other images. The term includes but is not limited to the meaning of “graphic” contemplated by the Society of Environmental Graphic Design.

The term “graphic sandwich” means one or more layers of materials including, in one non-exclusive example, two lighting panels, a substantially opaque sheet disposed between opposing inner surfaces of the two lighting panels, and one or more graphics mounted on or adjacent to opposing exterior surfaces of the two lighting panels.

The term “in situ” means in an operational environment following initial installation.

The term “sheet” means a substantially flat material disposed between opposing lighting panels.

The term “seal” and/or “sealed” means closed securely to render the apparatus and system disclosed in this document substantially watertight and/or airtight.

The term “uniformly” means substantially unchanging, to always display the graphics in the same quality, degree, character or manner in a consistent way.

The term “wayfinder” means at least an illuminable apparatus for guiding people through public areas.

### DESCRIPTION

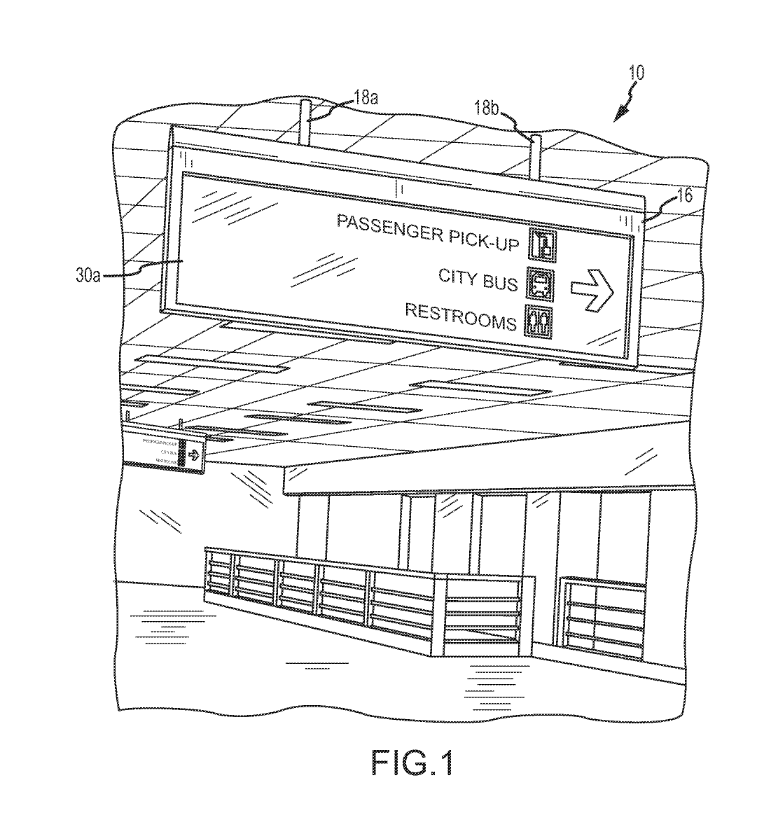

As shown in FIGS. 1-5B, an edge illuminable wayfinder is provided that in its broadest context includes a sealed light-emitting diode platform operatively connectable to an edge-illuminable graphic sandwich mounted in a housing in such a way that the graphic sandwich and LED platform are field-accessible.

More specifically, in one embodiment, a plurality of diodes is positioned on the sealed light-emitting diode platform in such a way that each of at least two lighting panels included in the edge-illuminable graphic sandwich are uniformly and brightly illuminable. If an edge illuminable wayfinder having a single graphic display is needed, a plurality of diodes is positioned on the sealed light-emitting diode platform in such a way that a single lighting panel is uniformly and brightly illuminable. A substantially opaque sheet disposed between opposing inner surfaces of a plurality of engraved lighting panels prevents light from bleeding between the two lighting panels, producing a uniform and bright illumination of wayfinder graphics that are removably positioned on the lighting panels. The combination of components enables the wayfinder to be illuminable by directing the light through a single edge of the illuminable graphic sandwich. Because components of the wayfinder are field accessible, selectively dissimilar graphics may be mounted on opposing outer surfaces of the two lighting panels to provide different information as needed; in other words, a double-faced edge illuminable graphic sandwich with a different graphic on each face is achieved. As indicated, however, the wayfinder also made be placed in an operative environment as a single-faced wayfinder. Accordingly, an apparatus is provided that includes an illuminable graphic sandwich that is operatively connectable to a sealed light-emitting diode platform.

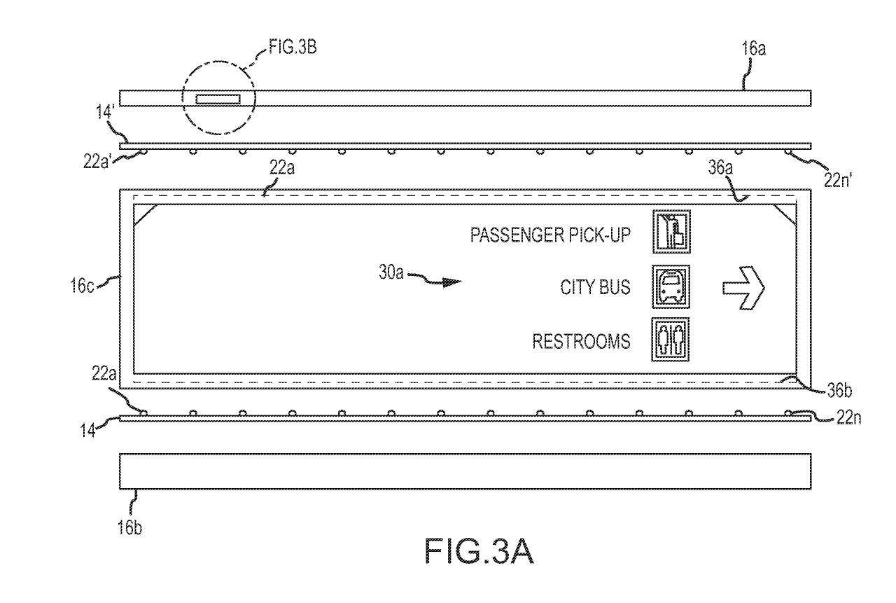

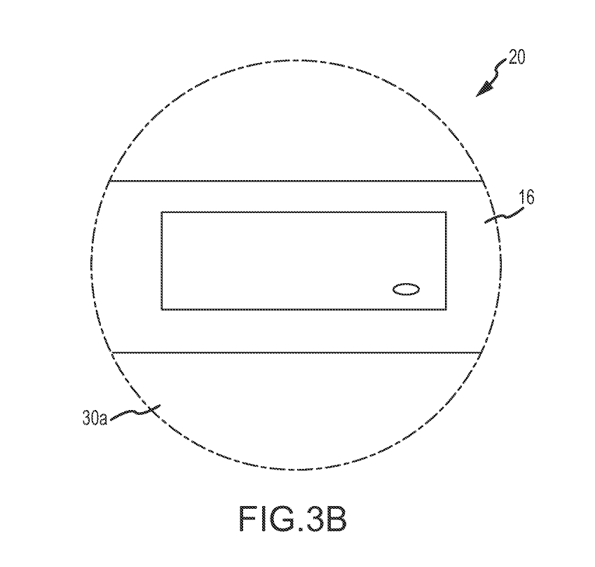

Thus, in one embodiment, as illustrated by cross-reference between FIGS. 1-5B, an apparatus 10 is provided that includes an illuminable graphic sandwich 12 that is operatively connectable to a sealed light-emitting diode platform 14. The apparatus 10 further comprises a housing 16. In at least one embodiment, the housing 16 is made of extruded aluminum to reduce operational temperatures within the apparatus 10. Likewise, other components of the apparatus 10 are also made of aluminum to reduce operating temperatures, but as a person skilled in the art will appreciate, the materials used in manufacturing the apparatus are not a limitation of the disclosure in this document. As illustrated in FIG. 3A, an alternative embodiment of sealed light-emitting diode platform 14 is shown as 14′ to indicate that in one or more aspects or embodiments the sealed light-emitting diode platform 14 may be installed in an edge illuminable wayfinder 10 at the top of edge illuminable wayfinder 10 rather than in the preferred position at the bottom of edge illuminable wayfinder 10. Accordingly, the plurality of diodes 34a-n is positioned on the sealed light-emitting diode platform 34 in such a way as to illuminate uniformly each of the plurality of lighting panels 22a,b by directing light from the plurality of diodes 34a-n to an opposing edge 36a or 36b, depending on where in the apparatus 10 the wayfinding needs of a customer dictate the positioning of the sealed light-emitting diode platform 34 of the illuminable graphic sandwich 12.

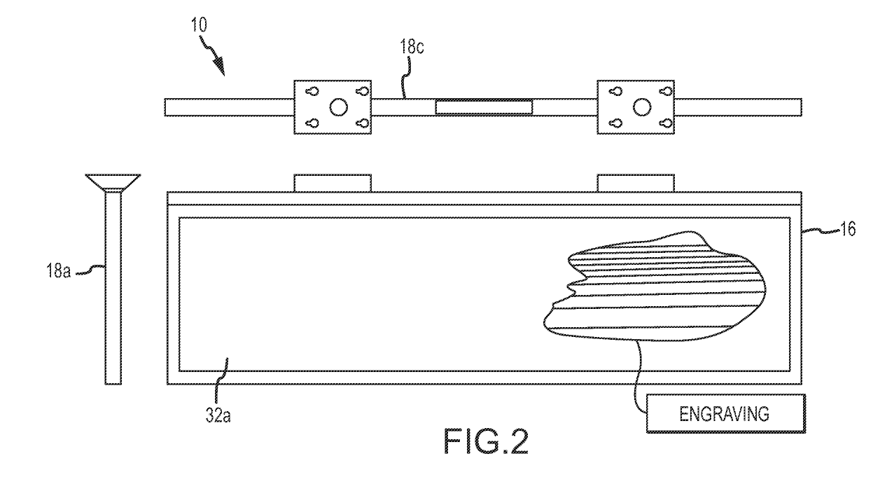

The edge illuminable graphic sandwich 12 and the sealed light-emitting diode platform 14 are removably enclosable in the housing 16. When assembled, the apparatus may be stationed in a public area as illustrated in FIG. 1 by suspending the 14 housing from a ceiling using the mounting devices 18a,b illustrated in FIG. 2, or by mounting the housing on a wall, or otherwise displaying the apparatus as a stem or flag. Components of the edge illuminable graphic sandwich 12 may be accessed either when the apparatus 10 is in a static configuration, or when the apparatus 10 has been placed in an operational environment. As illustrated by cross-reference between FIGS. 3A-3B, and as more fully described in this document below, at least one means for accessing the one or more components of the edge illuminable graphic sandwich is an access cover 20.

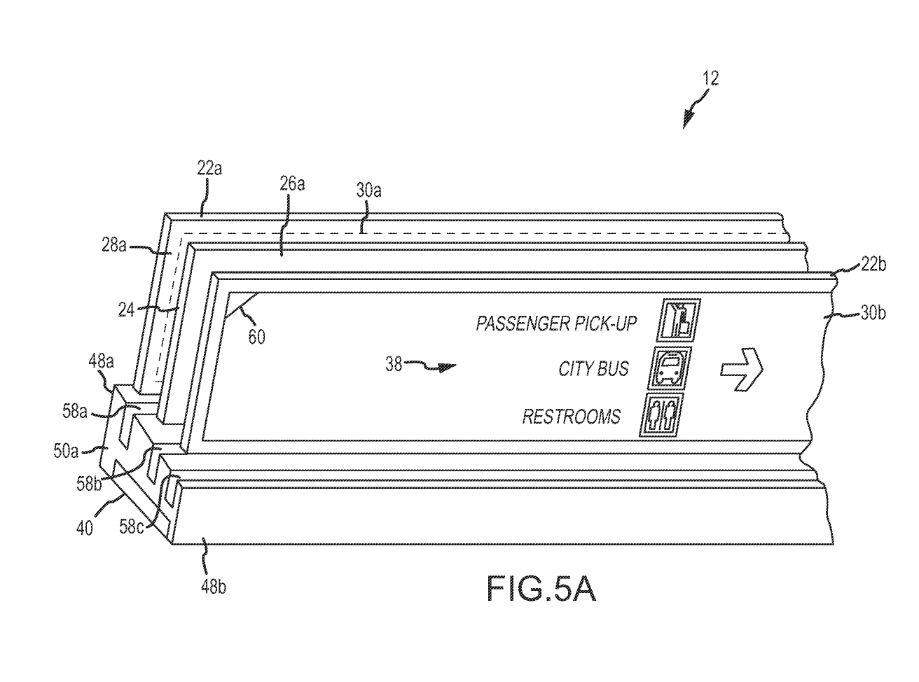

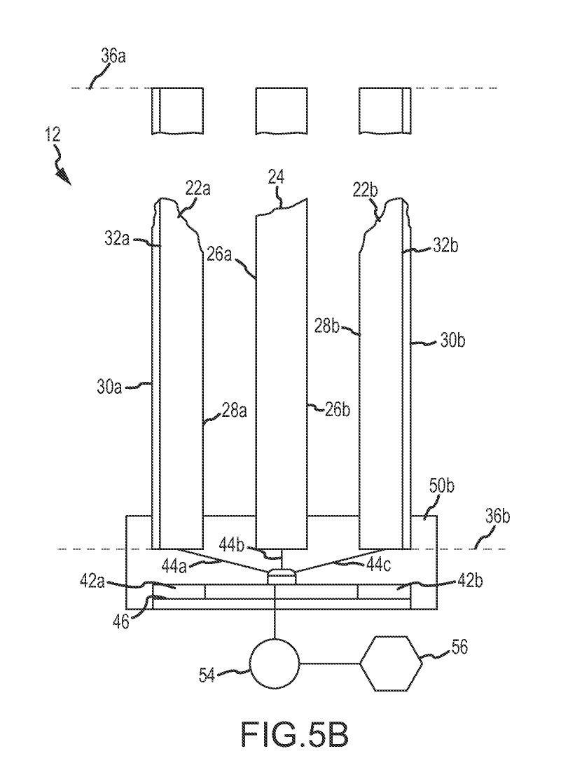

The edge illuminable graphic sandwich 12 includes a plurality of lighting panels 22a,b as perhaps best illustrated by cross-reference to FIG. 5A-5B. None of the shapes, thicknesses, or other configurations and/or dimensions suggested by FIGS. 5A and 5B is intended to suggest actual comparative or respective dimensions of the components of the edge illuminable wayfinder 10, but are shown only as an aid to understanding the disclosure. For example, the distances between the plurality of lighting panels 22a,b and/or opaque sheet 24 are exaggerated to enhance the description and understanding of the interrelationship of the components. Likewise, the opaque sheet 24, discussed in greater detail below, may be a comparatively thin sheet of material rather than the plate-like component illustrated.

Regarding the plurality of lighting panels 22a,b, at least one exemplary manipulable material used to fabricate the plurality of lighting panels 22a,b is white acrylic. In one embodiment, the white acrylic material is approximately ⅛ inch thick. In another embodiment, the plurality of lighting panels 22a,b may be made of polycarbonate, but as a person skilled in the art will appreciate, neither the material nor the dimensions of the material are limitations of the disclosures and claims in this document.

The edge illuminable graphic sandwich 12 also includes a substantially opaque sheet 24 as also illustrated by cross-reference between FIGS. 5A-5B. The embodiment illustrated in FIGS. 5A-5B show a substantially opaque sheet 24 is disposed between opposing inner surfaces 28a,b of the plurality of lighting panels 22a,b. At least one technical advantage of the substantially opaque sheet 24 is prevention of light bleeding, running, or fading of light (collectively “bleeding,” in this document) between and through the substantially opaque sheet 24 and the plurality of lighting panels 22a,b that might degrade or blur the graphics further described below. As a person skilled in the art will appreciate, the substantially opaque sheet 24 prevents bleeding of light between the plurality of lighting panels 22a,b because of the opacity of selected materials, which is the measure of impenetrability of, in this instance, light's capacity to pass through the selected material used to make the substantially opaque sheet 24. The substantially opaque material of the opaque sheet 24 is neither transparent nor translucent; the opaque sheet 24 transmits no light, and therefore reflects, scatters or absorbs light. Reflected and scattered light enters the plurality of lighting panels 22a,b positioned on opposing sides 26a,b of opaque sheet 24. The opaque sheet 24 thus contributes to achieving the uniformity and brightness of lighting in the plurality of lighting panels 22a,b.

In addition, the edge illuminable graphic sandwich 12 also includes one or more graphics 30a,b. The embodiment illustrated in FIGS. 5A-5B illustrates one or more graphics 30a,b mounted on or adjacent to opposing exterior surfaces 32a,b of the plurality of lighting panels 22a,b. At least one material used to fabricate the one or more graphics 30a,b is polycarbonate; other plastic materials may be used, but as a person skilled in the art will appreciate, such materials are not a limitation on the claims and disclosure of this document.

To enhance the uniform intensity and brightness of distributed light through, across and from the plurality of lighting panels 22a,b, either or both of the opposing inner surfaces 28a,b and the opposing exterior surfaces 32a,b of the plurality of lighting panels 22a,b may be engraved. Such engraving is partially illustrated in FIG. 2 by a cross-hatched portion with a legend. The term “engraved” means that at least one surface of a lighting panel 22a,b has been engraved or etched with a series of spaced-apart substantially parallel lines to increase the uniformity of distribution of light across a lighting panel 22a,b and to increase the brightness of a lighting panel 22a,b. This is yet another unique aspect of the edge illuminable wayfinder 10, and is achieved in one embodiment by using a laser device (not shown) to scribe onto a surface of the plurality of lighting panels 22a,b, including the opposing exterior surfaces 32a,b of the plurality of lighting panels 22a,b, the series of spaced apart lines. Depending on the lighting effect desired, the width, depth, and spacing of the engraved lines may be varied.

As illustrated in FIG. 2, the substantially parallel lines are shown to be spaced apart progressively closer together the more distant the spaced apart lines are from the sealed light-emitting diode platform 14. As a person skilled in the art will appreciate, propagation of light across a material like the plurality of lighting panels 22a,b begins to dissipate or scatter the more distant propagated light is from the source of light. However, a person skilled in the art also will appreciate that the series of spaced-apart substantially parallel lines will, through principles of reflection and refraction and transmission, cause the intensity and brightness of light that may have begun to diminish to instead be increased as light traverses the engraved lines on the plurality of lighting panels 22a,b, thus providing substantially uniform and bright light across each of the plurality of lighting panels 22a,b.

As a person skilled in the art also will appreciate, the one or more graphics 30a,b will generally include at least one visual display of words, symbols, pictures and/or other images (collectively, “images” 38) as illustrated in FIGS. 1 and 5A. In one embodiment, the one or more graphics 30a,b mounted on or adjacent to opposing exterior surfaces 32a,b of the plurality of lighting panels 22a,b is shaped from materials manufactured by the 3M Company of St. Paul, Minn., but as a person skilled in the art will appreciate, the selection and use of that material is not a limitation of the disclosures and claims in this document.

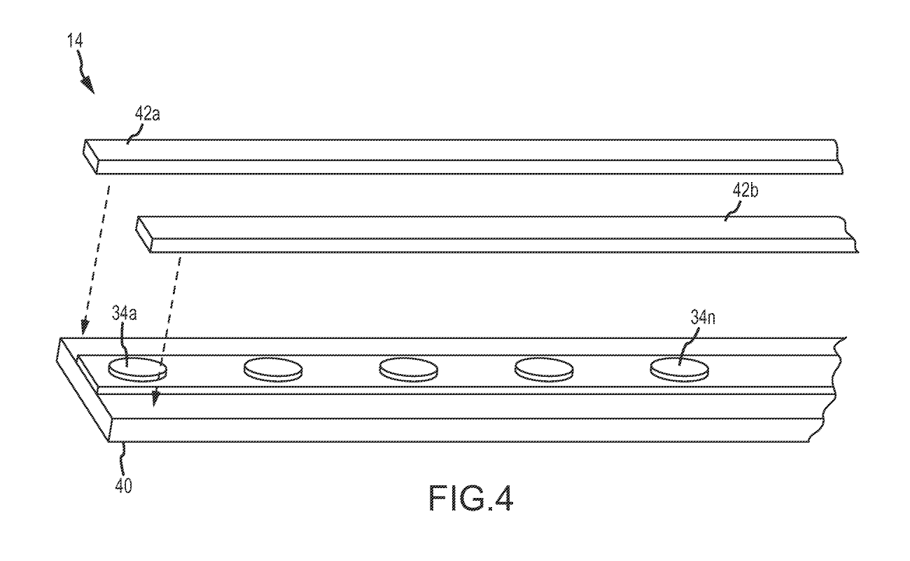

As illustrated by cross-reference between FIGS. 4 and 5B, the sealed light-emitting diode platform 14 includes a plurality of diodes 34a-n. The plurality of diodes 34a-n is positioned on the sealed light-emitting diode platform 34 in such a way as to illuminate uniformly each of the plurality of lighting panels 22a,b by directing light from the plurality of diodes 34a-n to an opposing edge 36a or 36b, depending on where in the apparatus 10 the wayfinding needs of a customer dictate the positioning of the sealed light-emitting diode platform 34 of the illuminable graphic sandwich 12. As illustrated in one nonexclusive embodiment in FIGS. 4 and 5B the plurality of diodes 34a-n is shown aligned substantially in a single line or file; in an alternative embodiment, not shown, the plurality of diodes 34a-n could be spaced apart in any number of alternative configurations. The plurality of diodes 34a-n, as illustrated, is positioned on a substrate 40 of the sealed light-emitting diode platform 34. Tests indicate that the sealed light-emitting diode platform 14 reduces energy consumption by approximately 50%, and extends this the useful life of the apparatus 10 by as much as 30,000 hours.

As also illustrated in FIG. 4, the sealed light-emitting diode platform 14 is sealed in a way to enable operation of the apparatus and neither a wet or dry environment. To enhance in understanding of the sealed light-emitting diode platform 34, seal 42 is shown to consist of two substantially parallel and spaced apart seals 42a,b as illustrated in FIG. 4. However, as a person skilled in the art will appreciate, the seal 42 may be any one or combination of materials that renders apparatus 10 substantially watertight and/or airtight following assembly in housing 16.

As illustrated diagrammatically in FIG. 5B, the sealed light-emitting diode platform 14 is operatively connectable to the illuminable graphic sandwich 12 as shown diagrammatically by lines 44a-c. Likewise, the light-emitting diode platform 14 may be disconnected from the illuminable graphic sandwich 12. As a result, both the light-emitting diode platform 14 and the illuminable graphic sandwich 12 are field accessible, allowing one or both to be serviced and/or replaced while installed in an operational environment.

The apparatus 10 also includes other means for accessing, removing and replacing one or more components of the sealed light-emitting diode platform 14 as well as the graphics 30a,b. In one nonexclusive example, the means for accessing, removing and replacing one or more components of the sealed light-emitting diode platform 14 and the graphics 30a,b is by opening and/or closing the access cover 20 of the housing 16. As illustrated, perhaps best by cross-reference between FIGS. 3A and 3B, the access cover 20 is a removably replaceable access cover 20.

Illustrated by cross-reference between FIGS. 5A-5B is a cavity 46 defined by opposing sides 48a,b and the opposing ends 50a,b of an extruded beam 52 positioned in the housing 16. In one embodiment, as illustrated diagrammatically in FIG. 5B, at least one a controller 54 and a power source 56. As illustrated diagrammatically, the controller 54 is operatively connectable to and detachable from the sealed light-emitting platform 12 which in turn is mounted in the housing 16 adjacent at least one edge 36a,b of the illuminable graphic sandwich 12.

In one embodiment of the light-emitting diode platform 14, is manufactured as a “plug and play” light-emitting diode platform 14 to simplify replacement of the light-emitting diode platform 14, if necessary. As manufactured, the light-emitting diode platform 14 includes thermal management features to reduce heat and to avoid the consequences of unexpectedly lower temperatures. Either DMX or easy interface to a 0-10 control device is provided.

In yet another embodiment, a method of uniformly displaying identical or different graphics 30a,b is provided that includes providing an illuminable graphic sandwich 12, forming a sealable light-emitting diode platform 14, connecting the illuminable graphic sandwich 12 and the light-emitting diode platform 14, energizing the sealable light-emitting diode platform 14, and enclosing removably the illuminable graphic sandwich 12 and the sealable light-emitting diode platform 14 in a housing 16. In one embodiment, as illustrated in FIG. 5B, at least one integral power source 56 is used to activate the sealable light-emitting diode platform 14. The result is that maintenance problems in connection with the method are significantly reduced.

The method further includes mounting one or more graphics 30a,b on or adjacent to opposing exterior surfaces 32a,b of the plurality of lighting panels 22a,b included in the illuminable graphic sandwich 12. In one embodiment, “lift and shift” graphic replacement is employed to enhance field accessibility. The graphics 30a,b are removably mountable on the opposing exterior surfaces 32a,b of the plurality of lighting panels 22a,b by any number of means including application of heat, stamp pressing, contact pressure. The combined graphics 30a,b and the plurality of lighting panels 22a,b are insertable into the plurality of grooves 58a,b formed in the extruded beam 52 which holds the graphics 30a,b on the opposing exterior surfaces 32a,b of the plurality of lighting panels 22a,b. In addition, one or more corner clips 60a,b may be inserted to hold the graphics 30a,b against the opposing exterior surfaces 32a,b of the plurality of lighting panels 22a,b. As illustrated in FIG. 5A, corner clips 60a,b are shown diagrammatically.

The method also includes selecting one or more sealing materials for the seal 42 from the group of materials consisting of rubber, resin, plastic, and insulation among other malleable and elastomeric materials.

Claim elements and steps in this document have been numbered solely as an aid in understanding the description. The numbering is not intended to, and should not be considered as intending to, indicate the ordering of elements and steps in the claims. In addition, the apparatus, methods and systems shown in drawing FIGS. 1 through 5B shows at least one aspect of the edge illuminable wayfinder, not intended to be exclusive, but merely illustrative of the disclosed embodiments.

Method steps may be interchanged sequentially without departing from the scope of the edge illuminable wayfinder.

Means-plus-function clauses in the claims are intended to cover the structures described as performing the recited function that include not only structural equivalents, but also equivalent structures. In addition, to improve the readability of the claims that include means-plus-function clauses, the means for displaying uniformly illuminable graphics is shortened in the dependent claims to “means for displaying”; and the means for illuminating the means for displaying uniformly illuminable removable graphics is abbreviated to “means for illuminating”; and the means for energizing the means for illuminating the means for displaying uniformly illuminable removable graphics is abbreviated to “means for energizing.”

Although the apparatus, systems, and methods provide for use with LED devices and technologies, that is not a limitation of future uses of the LED-enabled edge illuminable wayfinder, but only recognition of the current nature of LED technologies as sources of light and lighting which may, however, change over time.

What is claimed is:

1. An apparatus, comprising:
an illuminable graphic sandwich; and
a sealed light-emitting diode platform operatively connectable to the illuminable graphic sandwich.

2. An apparatus as recited in claim 1, further comprising a housing in which the illuminable graphic sandwich and the sealed light-emitting diode platform are removably enclosable.

3. An apparatus as recited in claim 2, wherein the edge illuminable graphic sandwich includes means for accessing one or more components of the edge illuminable graphic sandwich and the sealed light-emitting diode platform in a static or in an operational environment.

4. An apparatus as recited in claim 3, wherein the edge illuminable graphic sandwich includes one or more engraved lighting panels.

5. An apparatus as recited in claim 4, wherein the edge illuminable graphic sandwich further comprises a substantially opaque sheet disposed between the one or more engraved lighting panels.

6. An apparatus as recited in claim 5, wherein the edge illuminable graphic sandwich further comprises one or more removable graphics mounted on or adjacent to the one or more engraved lighting panels.

7. An apparatus as recited in claim 6, further comprising a plurality of diodes positioned on the sealed light-emitting diode platform in such a way as to illuminate uniformly each of the one or more engraved lighting panels by directing light to an edge of the illuminable graphic sandwich.

8. An apparatus as recited in claim 7, wherein the sealed light-emitting diode platform is operatively connectable to the illuminable graphic sandwich in such a way that the sealed light-emitting diode platform is field accessible.

9. An apparatus as recited in claim 8, wherein the apparatus includes means for accessing, removing and replacing in situ one or more components of the apparatus.

10. An edge illuminable wayfinder, comprising:
an illuminable graphic sandwich,
wherein the illuminable graphic sandwich includes a plurality of engraved lighting panels, a substantially opaque sheet disposed between opposing inner surfaces of the a plurality of engraved lighting panels, and one or more removable and replaceable graphics mounted on or adjacent to opposing exterior surfaces of the plurality of engraved lighting panels;
a removably replaceable light-emitting diode platform operatively connectable to the illuminable graphic sandwich,
wherein the light-emitting diode platform uniformly and brightly displays the one or more replaceable graphics;
and further wherein the light-emitting diode platform is sealed in such a way as to enable operation of the edge illuminable wayfinder in either a wet or dry environment; and
a housing for removably enclosing the illuminable graphic sandwich and the light-emitting diode platform.

11. An illuminating system, comprising:
means for displaying uniformly illuminable graphics;
means for illuminating the means for displaying uniformly illuminable removable graphics; and
means for energizing the means for illuminating the means for displaying uniformly illuminable removable graphics,
wherein the means for energizing is operatively connectable to the means for displaying and to the means for illuminating.

12. An illuminating system as recited in claim 11, further comprising means for surroundingly enclosing and mounting on a surface the means for displaying, the means for illuminating, and the means for energizing.

13. An illuminating system as recited in claim 11, wherein the means for displaying includes an illuminable graphic sandwich.

14. An illuminating system as recited in claim 11, wherein the means for illuminating includes one or more removable light-emitting diode platforms operatively connectable to the means for displaying.

15. An illuminating system as recited in claim 13, wherein the means for energizing is operatively connectable to the means for illuminating in such a way that the illuminating system produces uniformly brightly illuminated graphics by energizing one edge of the illuminable graphic sandwich.

16. An illuminating system as recited in claim 12, wherein the means for energizing and the means for illuminating are sealed in the means for surroundingly enclosing and mounting on a surface in such a way as to enable operation of the illuminating system in a wet or dry environment.

17. A method of uniformly displaying graphics, comprising:
providing an illuminable graphic sandwich;
forming a sealable light-emitting diode platform;
connecting the illuminable graphic sandwich and the light-emitting diode platform;
energizing the sealable light-emitting diode platform; and
enclosing removably the illuminable graphic sandwich and the sealable light-emitting diode platform in a housing.

18. A method of uniformly displaying graphics as recited in claim 17, wherein providing an illuminable graphic sandwich includes:
manipulating one or more materials to form a plurality of lighting panels;
engraving lines of variable width, depth and spacing on one or more surfaces of the plurality of lighting panels;
disposing a substantially opaque sheet between opposing inner surfaces of the plurality of lighting panels;
mounting one or more graphics on or adjacent to opposing exterior surfaces of the plurality of lighting panels, wherein the one or more graphics includes at least a visual display of words, symbols, pictures and/or other images; and
manufacturing the illuminable graphic sandwich in such a way that the components of the illuminable graphic sandwich are field accessible.

19. A method of uniformly displaying graphics as recited in claim 18, wherein forming a sealable light-emitting diode platform includes:
shaping a substrate for mounting a plurality of light-emitting diodes;
selecting one or more light-emitting diodes;
positioning the one or more light-emitting diodes on the substrate in such a way that the plurality of lighting panels are uniformly lightable by directing the light from the one or more light-emitting diodes to an edge of the illuminable graphic sandwich;
attaching a source of power to the sealable light-emitting diode platform; and
energizing the source of power.

20. A method of uniformly displaying graphics as recited in claim 19, wherein forming a sealable light-emitting diode platform includes selecting one or more sealing materials from the group of materials consisting of rubber, resin, plastic, and insulation among other malleable and elastomeric materials.
